(19) United States
(12) Patent Application Publication
(10) Pub. No.: US 2013/0105201 A1
(43) Pub. Date: May 2, 2013

(54) ELECTRONIC COMPONENT-EMBEDDED PRINTED CIRCUIT BOARD AND METHOD OF MANUFACTURING THE SAME

(71) Applicants: Jong In Ryu, Chungcheongnam-do (KR); Jin Won Lee, Gyeonggi-do (KR); Yul Kyo Chung, Gyeonggi-do (KR)

(72) Inventors: Jong In Ryu, Chungcheongnam-do (KR); Jin Won Lee, Gyeonggi-do (KR); Yul Kyo Chung, Gyeonggi-do (KR)

(73) Assignee: SAMSUNG ELECTRO-MECHANICS CO., LTD., Suwon (KR)

(21) Appl. No.: 13/483,753

(22) Filed: May 30, 2012

(30) Foreign Application Priority Data
Oct. 27, 2011 (KR) 10-2011-0110473

(51) Int. Cl. H05K 1/16; H05K 3/30

(52) U.S. Cl. 174/251; 29/841

(57) ABSTRACT

An electronic component-embedded printed circuit board and a method of manufacturing the same. The printed circuit board includes a base substrate including a hollow electronic component case, an electronic component inserted into the electronic component case, circuit pattern layers formed on upper and lower surfaces of the base substrate, and an insulating layer formed to cover the circuit pattern layers. Accordingly, since the printed circuit board includes the electronic component case formed therein and the electronic component is inserted into only the printed circuit board, which has no defect after manufacture and final inspection of the printed circuit board, component loss due to yield of the printed circuit board can be reduced.

### CROSS-REFERENCE TO RELATED APPLICATIONS

This application claims the benefit of Korean Patent Application No. 10-2011-0110473 filed with the Korea Intellectual Property Office on Oct. 27, 2011, the disclosure of which is incorporated herein by reference.

### BACKGROUND OF THE INVENTION

1. Field of the Invention

The present invention relates to an electronic component-embedded printed circuit board and a method of manufacturing the same, and more particularly, to an electronic component-embedded printed circuit board capable of reducing loss in substrate yield and enabling mass production and easy upgrade by detachably forming the electronic component embedded into the printed circuit board, and a method of manufacturing the same.

2. Description of the Related Art

According to market tendency requiring reduction in profile and various functions in a semiconductor package, various techniques are required to implement a printed circuit board.

For example, in manufacturing a flip chip ball grid array (FCBGA) package, an electrical conductive terminal or land of an integrated circuit (IC) component is directly soldered to a corresponding land of a die bond region on a surface of a substrate using a solder bump or ball, which can be reflowed.

Here, an electronic component or components are functionally connected to another device of an electronic system through a layer of an electrical conductive path including a substrate trace, and the substrate trace transports a signal, which is generally transmitted between electronic components such as ICs, etc., of the system. In the case of the FCBGA, an IC at an upper end of the substrate and a capacitor at a lower end thereof can be surface-mounted, respectively. In this case, a path of the circuit connecting the IC and the capacitor is increased by a thickness of the substrate to increase an impedance value, badly affecting electrical performance. In addition, since a certain area of a lower end surface must be used for mounting a chip, for example, requirements of a user who wants a ball array disposed on the entire surface of the lower end cannot be satisfied, limiting the degree of design freedom.

In order to solve the problems, a component mounting technique in which components are inserted into the substrate to reduce the path of the circuit has been proposed.

An electronic component-embedded printed circuit board can mount active/passive electronic components, which were mounted on a conventional substrate in a package, on a previously manufactured organic substrate to satisfy a multi-function as a marginal surface area is secured, radio frequency low loss/high efficiency technique due to minimization of a signal transmission line, and expectation of miniaturization, realizing a next-generation three-dimensional package technique and extracting a novel high-function packaging trend.

Here, specifically reviewing a conventional process of manufacturing an electronic component-embedded printed circuit board, the electronic component-embedded printed circuit board is manufactured through the steps of preparing a substrate body having a cavity in which electronic components can be disposed and including an insulating layer with circuit patterns formed at both surfaces thereof and a tape attached to one surface of the insulating layer, disposing the electronic components in the cavity of the insulating layer, depositing the insulating layer in the cavity in which the electronic components are disposed and burying the electronic components in an insulating material, removing the tape when the electronic components are fixed to the substrate body by the insulating material, and forming a circuit layer including vias and circuit patterns formed at both surfaces of the insulating material.

However, since the electronic component-embedded printed circuit board needs to contain the electronic components themselves, if there is a bad electronic component, the entire printed circuit board must be wasted.

Accordingly, yield of the components and the substrate affects the entire production cost, and thus, it is difficult to mount expensive components on the substrate.

### RELATED ART DOCUMENT

### Patent Document

1. KR 10-2010-0133768A

### SUMMARY OF THE INVENTION

The present invention has been invented in order to overcome the above-described problems and it is, therefore, an object of the present invention to provide an electronic component-embedded printed circuit board capable of reducing component loss due to substrate yield by detachably forming the electronic components, rather than directly mounting the electronic components in a printed circuit board, and a method of manufacturing the same.

It is another object of the present invention to provide an electronic component-embedded printed circuit board capable of reducing space loss due to a cavity by forming a metal pattern layer on an outer surface of a case formed in a printed circuit board, and a method of manufacturing the same.

In accordance with one aspect of the present invention to achieve the object, there is provided an electronic component-embedded printed circuit board, including: a base substrate including a hollow electronic component case; an electronic component inserted into the electronic component case; circuit pattern layers formed on upper and lower surfaces of the base substrate; and an insulating layer formed to cover the circuit pattern layers.

Here, the electronic component case may be formed at one side of the base substrate to expose an opening thereof.

In addition, the electronic component case may include a plurality of connecting terminals formed to be connected to the electronic component.

Further, the electronic component may include a plurality of solder balls formed to be connected to the electronic component case.

Meanwhile, the base substrate may further include a via configured to connect the circuit pattern layers formed on the upper and lower surfaces.

Here, the base substrate may be formed of a copper clad laminate (CCL) or epoxy-based resin.

In addition, the insulating layer may be formed of a solder resist layer.

Further, the electronic component case may have a circuit pattern layer formed on an outer surface thereof.

Furthermore, the insulating layer may be formed of a deposited buildup layer.

In accordance with another aspect of the present invention to achieve the object, there is provided a method of manufacturing an electronic component-embedded printed circuit board, including: (A) preparing a base substrate having a copper laminate formed thereon; (B) forming a cavity in the base substrate and attaching a support tape to one surface of the base substrate; (C) disposing an electronic component case in the cavity; (D) removing the support tape of the base substrate and forming a circuit pattern layer; (E) depositing an insulating layer on the base substrate; and (F) inserting an electronic component into the electronic component case.

Here, the electronic component case may have a circuit pattern layer formed on an outer surface thereof.

Meanwhile, in step (C), the electronic component case may be disposed at one side of the base substrate to expose an opening of the case.

In addition, the electronic component case may have a plurality of connecting terminals formed to be connected to the electronic component.

Further, in step (E), the insulating layer may be formed of a solder resist layer.

Furthermore, in step (E), the insulating layer may be formed of a deposited buildup layer.

Here, the electronic component may have a plurality of solder balls formed to be connected to the electronic component case.

Meanwhile, the method may further include, after step (F), filling an insulating material in the electronic component case to cure the insulating material.

### BRIEF DESCRIPTION OF THE DRAWINGS

These and/or other aspects and advantages of the present general inventive concept will become apparent and more readily appreciated from the following description of the embodiments, taken in conjunction with the accompanying drawings of which:

FIG. 1 is a cross-sectional view showing an electronic component-embedded printed circuit board in accordance with an exemplary embodiment of the present invention;

FIG. 2 is a cross-sectional view showing an electronic component-embedded printed circuit board in accordance with another exemplary embodiment of the present invention;

FIG. 3 is an enlarged cross-sectional view of a portion A of FIG. 2; and

FIGS. 4 to 10 are cross-sectional views showing a process of manufacturing an electronic component-embedded printed circuit board in accordance with an exemplary embodiment of the present invention.

### DETAILED DESCRIPTION OF THE PREFERABLE EMBODIMENTS

Hereinafter, a specific embodiment of the present invention will be described in detail with reference to the accompanying drawings. The following embodiments are provided as examples to fully convey the spirit of the invention to those skilled in the art.

Hereinafter, exemplary embodiments of the present invention will be described in detail. However, the present invention is not limited to the embodiments disclosed below but can be implemented in various forms. The following embodiments are described in order to enable those of ordinary skill in the art to embody and practice the present invention. To clearly describe the present invention, parts not relating to the description are omitted from the drawings.

The following embodiments are provided as examples to fully convey the spirit of the invention to those skilled in the art. Therefore, the present invention should not be construed as limited to the embodiments set forth herein and may be embodied in different forms.

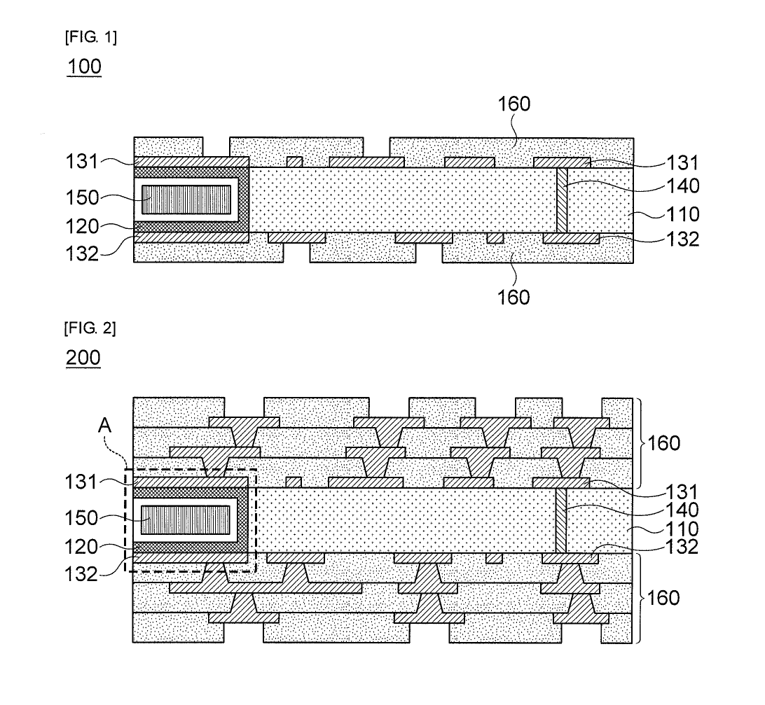

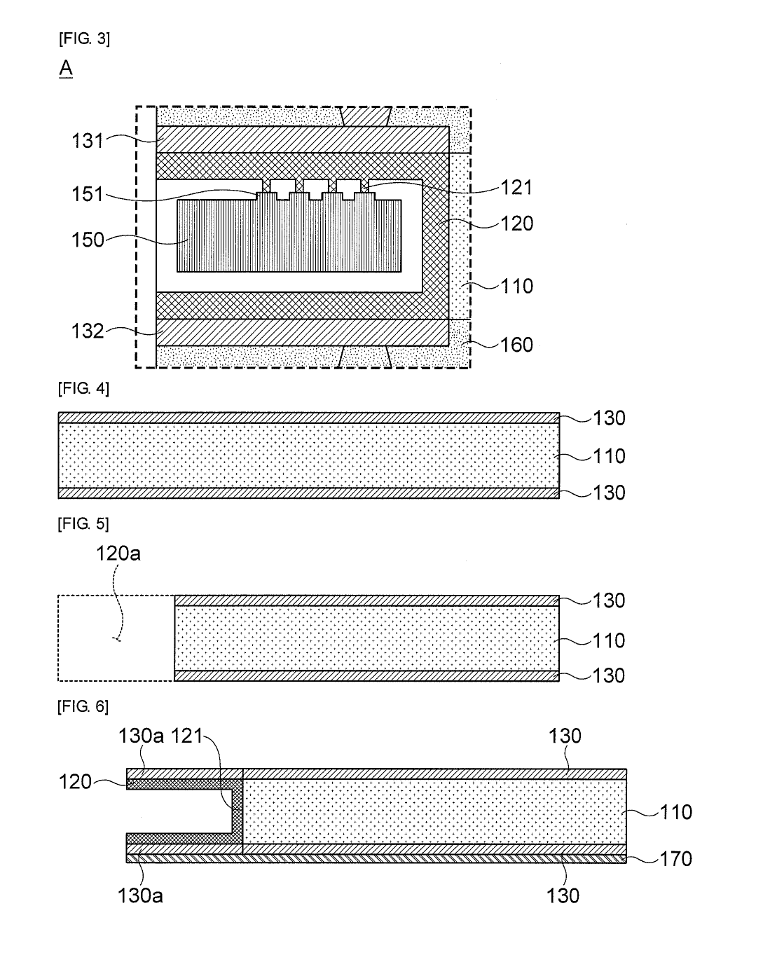

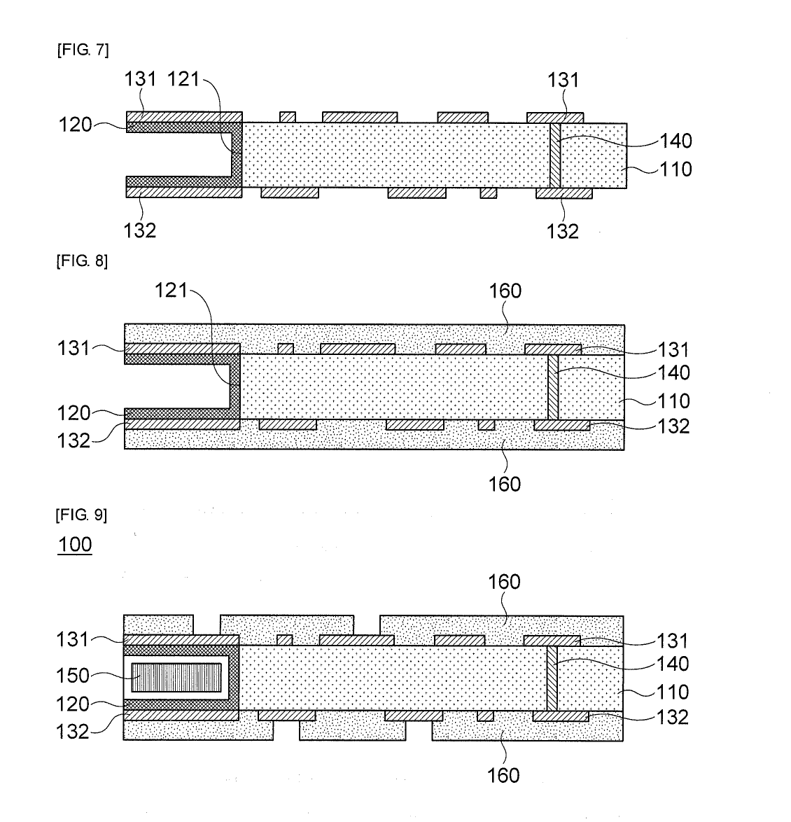

FIG. 1 is a cross-sectional view showing an electronic component-embedded printed circuit board in accordance with an exemplary embodiment of the present invention, FIG. 2 is a cross-sectional view showing an electronic component-embedded printed circuit board in accordance with another exemplary embodiment of the present invention, and FIG. 3 is an enlarged cross-sectional view of a portion A of FIG. 2.

As shown in FIGS. 1 to 3, the electronic component-embedded printed circuit board in accordance with an exemplary embodiment of the present invention includes a base substrate 110 having an electronic component case 120 having a hollow inner space, an electronic component 150 inserted into the electronic component case 120, circuit pattern layers 131 and 132 formed on upper and lower surfaces of the base substrate 110, and an insulating layer 160 formed to cover the circuit pattern layers 131 and 132.

The base substrate 110 may be formed using a copper clad laminate (CCL) including a core or epoxy-based resin.

In addition, the base substrate 110 may have a cavity 120a formed at one side of the base substrate 110 such that the electronic component case 120 into which the electronic component 150 is inserted is disposed in the cavity 120a.

The cavity 120a may be formed by removing a predetermined portion of one side of the base substrate 110 through a wet etching process or a dry etching process. However, a method of forming the cavity 120a is not limited thereto but may be any method as long as a predetermined portion of the base substrate 110 is removed through drill machining using any one of a mechanical drill, a CO₂ laser drill and an Nd-Yag laser drill.

The electronic component case 120 may be formed in the cavity 120a formed as described above.

Here, the electronic component case 120 has an opening, into which the electronic component 150 is inserted to be electrically connected, formed at one side of the base substrate 110 to be exposed to the outside, and the electronic component 150 may be configured to slide to be inserted into the opening of the electronic component case 120.

In addition, the electronic component case 120 may be formed of a metal material having good strength and thermal conductivity such as aluminum (Al), magnesium (Mg), titanium (Ti), and so on.

Further, as shown in FIG. 3, a plurality of connecting terminals 121 may be formed in the electronic component case 120 to be electrically connected to the inserted electronic component 150. Here, the connecting terminals 121 may be formed as a plurality of pins to be connected to electrodes of the electronic component 150.

Furthermore, the connecting terminals 121 may be formed of the same material as the electronic component case 120.

Here, the circuit pattern layers 131 and 132 may be formed at the outside of the electronic component case 120 to be electrically connected to the electronic component 150 inserted into the electronic component case 120 via the connecting terminals 121.

Meanwhile, the electronic component 150 inserted into the electronic component case 120 is a component electrically connected to the printed circuit board to perform a certain function, which may be an active device such as a semiconductor device or an active device such as a capacitor.

Here, the electronic component 150 may be formed in the electronic component case 120, and may be mounted in a face-up manner such that terminals of the electronic component 150 can be connected to the connecting terminals 121.

Here, the terminals 151 of the electronic component 150 may be a metal bump or a metal pad. In addition, solder balls (not shown) may be formed at the terminals 151 to be connected to the connecting terminals 121 of the electronic component case 120.

In addition, in order to fix the electronic component 150 inserted into the electronic component case 120, an insulating material may be filled in a space between the electronic component 150 and the electronic component case 120. Further, the electronic component 150 instead of the insulating material is formed to correspond to a size of the electronic component case 120 so that the electronic component 150 and the electronic component case 120 can be coupled to each other with no gap therebetween upon insertion.

In this embodiment, while the connecting terminals 121 are formed at an inner upper part of the electronic component case 120 such that the electronic component 150 is installed in a face-up manner, the connecting terminals 121 may be formed at an inner lower part of the electronic component case 120 such that the electronic component 150 is installed in a face-down manner.

The circuit pattern layers 131 and 132 may be formed on upper and lower surfaces of the base substrate 110, and the circuit pattern layers 131 and 132 formed on the upper and lower surfaces of the base substrate 110 may be electrically connected by a via 140.

Here, the circuit pattern layers 131 and 132 formed on the upper and lower surfaces of the electronic component case 120 may be electrically connected to the electronic component 150 inserted into the electronic component case 120.

Here, the circuit pattern layers 131 and 132 and the via 140 may be formed through generally a subtractive technique or an additive technique according to a manufacturing process.

The subtractive technique may be referred to as a tent and etch technique because a portion at which a circuit pattern layer is to be formed and the inside of a hole in which the via is to be formed are processed generally using photo resist through tenting and etching. In this technique, a portion of copper laminate on which the circuit pattern layer is to be formed is exposed and the other portion of the copper laminate is etched to form the circuit pattern layer.

The additive technique is a technique of forming a circuit pattern layer by plating a conductive material on an insulating substrate using a selective extraction method through electroless plating or electrolysis plating. Here, the additive technique is classified as a full-additive technique or a semi-additive technique according to presence of a seed layer for electrolysis copper plating.

Meanwhile, the insulating layer 160 may be formed to cover the circuit pattern layers 131 and 132.

Here, the insulating layer 160 may be formed of a solder resist layer.

Here, the solder resist layer, which is a heat-resistant coating material, functions to protect outermost circuit pattern layers 131 and 132 so that solder is not applied to the layers 131 and 132 upon soldering. In addition, the opening for electrical connection to an external circuit may be formed to expose portions of the circuit pattern layers 131 and 132.

Meanwhile, as shown in FIG. 2, the insulating layer 160 may be formed by a deposited buildup layer. Here, the buildup layer may be deposited and formed on both surfaces of the base substrate 110. Here, the buildup layer may be completed by depositing a separate insulating material and forming a via-hole using a CO2 laser drill or an Nd-Yag laser drill, and then, forming a circuit layer including a via using the additive technique.

Hereinafter, a method of manufacturing an electronic component-embedded printed circuit board in accordance with the present invention will be described with reference to the accompanying drawings.

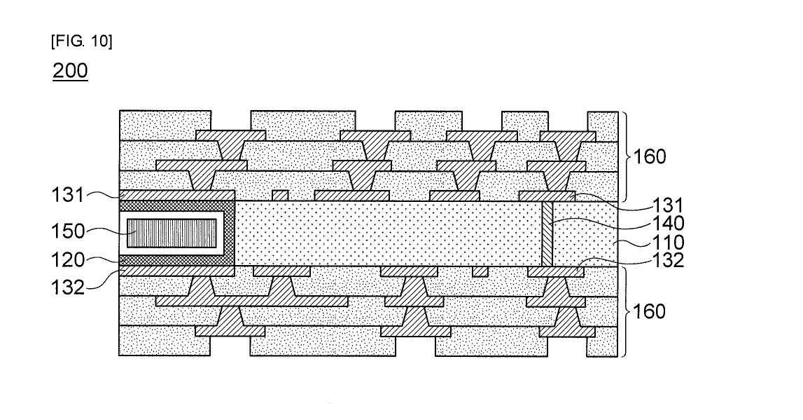

FIGS. 4 to 10 are cross-sectional views showing a process of manufacturing an electronic component-embedded printed circuit board in accordance with an exemplary embodiment of the present invention.

As shown in FIGS. 4 to 10, a method of manufacturing an electronic component-embedded printed circuit board in accordance with an exemplary embodiment of the present invention includes (A) preparing a base substrate 110 on which a copper laminate 130 is formed; (B) forming a cavity 120a in the base substrate 110 and attaching a support tape 170 to one surface of the base substrate 110; (C) disposing an electronic component case 120 in the cavity 120a; (D) removing the support tape 170 from the base substrate 110 to form circuit pattern layers 131 and 132; (E) depositing an insulating layer 160 on the base substrate 110; and (F) inserting an electronic component 150 into the electronic component case 120.

First, as shown in FIG. 4, the base substrate 110 is prepared. Here, the base substrate 110 may be formed of an insulating material, which is generally used in a printed circuit board, for example, a copper clad laminate (CCL) or epoxy-based resin.

Next, as shown in FIG. 5, a cavity 121 may be formed at one side of the prepared base substrate 110. Here, the cavity 121 may be formed by removing a predetermined portion of one side of the base substrate 110 through a wet etching process or a dry etching process, or a drill machining using any one of a CO₂ layer drill and an Nd-Yag laser drill.

Next, as shown in FIG. 6, the base substrate 110 having the cavity 121 is attached and fixed to the support tape 170, and the electronic component case 120 is disposed in the cavity 121. Here, the electronic component case 120 may be disposed at one surface of the base substrate 110 to expose the opening to the outside. Here, the electronic component case 120 may be formed of a metal such as aluminum (Al), magnesium (Mg), titanium (Ti), and so on, having good strength and thermal conductivity. In addition, metal layers 130a having the same thickness as the copper laminate 130 of the base substrate 110 may be formed on upper and lower surfaces of the electronic component case 120.

Next, as shown in FIG. 7, the support tape 170 may be removed and the circuit pattern layers 131 and 132 and the via 140 may be formed at the base substrate 110. Here, a via-hole (not shown) may be formed on the base substrate 110 using a drill (a mechanical drill or a laser drill), and the circuit pattern layers 131 and 132 and the via 140 may be formed through the subtractive technique or the additive technique.

Next, as shown in FIG. 8, the insulating layer 160 may be formed to cover the circuit pattern layers 131 and 132. At this time, the insulating layer 160 may be a solder resist layer.

Next, as shown in FIG. 9, an opening is formed in the solder resist layer to expose portions of the circuit pattern layers 131 and 132, and the electronic component 150 can be slidably inserted into the electronic component case 120. Here, the electronic component 140 may be inserted with a protective member (not shown) formed thereon.

In addition, after inserting the electronic component 150, an insulating material may be injected to fill an empty space between the electronic component case 120 and the electronic component 150.

Meanwhile, as another method of removing an empty space between the electronic component case 120 and the electronic component 150, the electronic component 150 may be formed to have the same size as an inner space of the electronic component case 120.

Next, as shown in FIG. 10, the insulating layers 160 formed at both surfaces of the base substrate 110 are formed as buildup layers, and the electronic component 150 may be slidably inserted into the electronic component case 120. Here, the buildup layers may form a circuit layer including a via using the additive technique after depositing a separate insulating material and forming a via-hole using the CO₂ laser drill or the Nd-Yag laser drill.

The electronic component-embedded printed circuit board in accordance with the present invention as described above includes the electronic component case 120 such that the electronic component 150 can be inserted in a final step of a process of manufacturing the printed circuit board. Accordingly, even when a bad printed circuit board is produced during the manufacturing process, there is no loss of the electronic component 150. In addition, when a bad electronic component 150 is produced, since only the electronic component 150 can be exchanged with a new one, loss of the printed circuit board and the components due to the inferiority can be reduced.

Further, since various design applications may be applied by varying only the inserted electronic component while using the same printed circuit board, the printed circuit board can be used as a platform to enable mass production and upgrade of the printed circuit board.

As can be seen from the foregoing, in the electronic component-embedded printed circuit board and a method of manufacturing the same in accordance with an exemplary embodiment of the present invention, since the printed circuit board includes the electronic component case formed therein and the electronic component is inserted into only the printed circuit board, which has no defect after manufacture and final inspection of the printed circuit board, component loss due to yield of the printed circuit board can be reduced.

In addition, in the electronic component-embedded printed circuit board and a method of manufacturing the same in accordance with an exemplary embodiment of the present invention, since various design applications may be applied by varying only the inserted electronic component while using the same printed circuit board, the printed circuit board can be used as a platform to enable mass production and upgrade of the printed circuit board.

Further, in the electronic component-embedded printed circuit board and a method of manufacturing the same in accordance with an exemplary embodiment of the present invention, since the metal pattern layer is formed at the outer surface of the electronic component case installed in the printed circuit board, space loss due to the conventional cavity can be reduced.

As described above, although the preferable embodiments of the present invention have been shown and described, it will be appreciated by those skilled in the art that substitutions, modifications and variations may be made in these embodiments without departing from the principles and spirit of the general inventive concept, the scope of which is defined in the appended claims and their equivalents.

1. An electronic component-embedded printed circuit board, comprising:
a base substrate including a hollow electronic component case;
an electronic component inserted into the electronic component case;
circuit pattern layers formed on upper and lower surfaces of the base substrate; and
an insulating layer formed to cover the circuit pattern layers.

2. The electronic component-embedded printed circuit board according to claim 1, wherein the electronic component case is formed at one side of the base substrate to expose an opening thereof.

3. The electronic component-embedded printed circuit board according to claim 1, wherein the electronic component case comprises a plurality of connecting terminals formed to be connected to the electronic component.

4. The electronic component-embedded printed circuit board according to claim 1, wherein the electronic component comprises a plurality of solder balls formed to be connected to the electronic component case.

5. The electronic component-embedded printed circuit board according to claim 1, wherein the base substrate further comprises a via configured to connect the circuit pattern layers formed on the upper and lower surfaces.

6. The electronic component-embedded printed circuit board according to claim 1, wherein the base substrate is formed of a copper clad laminate (CCL) or epoxy-based resin.

7. The electronic component-embedded printed circuit board according to claim 1, wherein the insulating layer is formed of a solder resist layer.

8. The electronic component-embedded printed circuit board according to claim 1, wherein the electronic component case has a circuit pattern layer formed on an outer surface thereof.

9. The electronic component-embedded printed circuit board according to claim 1, wherein the insulating layer is formed of a deposited buildup layer.

10. A method of manufacturing an electronic component-embedded printed circuit board, comprising:
preparing a base substrate having a copper laminate formed thereon;
forming a cavity in the base substrate and attaching a support tape to one surface of the base substrate;
disposing an electronic component case in the cavity;
removing the support tape of the base substrate and forming a circuit pattern layer;
depositing an insulating layer on the base substrate; and
inserting an electronic component into the electronic component case.

11. The method of manufacturing an electronic component-embedded printed circuit board according to claim 10, wherein the electronic component case has a circuit pattern layer formed on an outer surface thereof.

12. The method of manufacturing an electronic component-embedded printed circuit board according to claim 10, wherein, in the disposing, the electronic component case is disposed at one side of the base substrate to expose an opening of the case.

13. The method of manufacturing an electronic component-embedded printed circuit board according to claim 10, wherein the electronic component case has a plurality of connecting terminals formed to be connected to the electronic component.

14. The method of manufacturing an electronic component-embedded printed circuit board according to claim 10, wherein, in the depositing, the insulating layer is formed of a solder resist layer.

15. The method of manufacturing an electronic component-embedded printed circuit board according to claim 10, wherein, in the depositing, the insulating layer is formed of a deposited buildup layer.

16. The method of manufacturing an electronic component-embedded printed circuit board according to claim 10, wherein the electronic component has a plurality of solder balls formed to be connected to the electronic component case.

17. The method of manufacturing an electronic component-embedded printed circuit board according to claim 10, further comprising, after the inserting, filling an insulating material in the electronic component case to cure the insulating material.
